(19) United States
(12) Patent Application Publication
(10) Pub. No.: US 2024/0224480 A1
(43) Pub. Date: Jul. 4, 2024

(54) MIDDLE FRAME ASSEMBLY AND DISPLAY APPARATUS

(71) Applicant: Shanghai Tianma Microelectronics Co., Ltd., Shanghai (CN)

(72) Inventors: Shouzheng WU, Shanghai (CN); Yongxin HE, Shanghai (CN)

(73) Assignee: Shanghai Tianma Microelectronics Co., Ltd., Shanghai (CN)

(21) Appl. No.: 18/607,939

(22) Filed: Mar. 18, 2024

(30) Foreign Application Priority Data
Aug. 14, 2023 (CN) 202311020565.1

(51) Int. Cl. H05K 7/20; H05K 9/00

(52) U.S. Cl. CPC H05K 7/20963; H05K 9/0054

(57) ABSTRACT

A middle frame assembly and a display apparatus are provided. In an embodiment, the middle frame assembly includes: a middle frame, a back cover, a homothermal structure, and a radiating fin. In an embodiment, the accommodating cavity is formed between the back cover and the middle frame. In an embodiment, the homothermal structure is located in the accommodating cavity. In an embodiment, the radiating fin is located in the accommodating cavity. In an embodiment, a contact area between the radiating fin and the homothermal structure is changeable.

### CROSS-REFERENCE TO RELATED DISCLOSURE

The present disclosure claims priority to Chinese Patent Application No. 202311020565.1, filed on Aug. 14, 2023, the content of which is incorporated herein by reference in its entirety.

### TECHNICAL FIELD

The present disclosure relates to the field of display technologies, and in particular, to a middle frame assembly and a display apparatus.

### BACKGROUND

In operation, a display apparatus generates significant heat. If this heat is not dissipated in time, it can lead to damage to the electronic devices within the display apparatus, thereby adversely affecting its service life.

Currently, the typical method of heat dissipation in display apparatuses involves attaching a complete radiating fin between the back cover and the middle frame. However, this approach is relatively simplistic and fails to meet the diverse heat dissipation requirements of users in different usage scenarios, resulting in poor user experience.

### SUMMARY

One aspect of the present disclosure provides a middle frame assembly. In an embodiment, the middle frame assembly includes a middle frame, a back cover, a homothermal structure, and a radiating fin. In an embodiment, the accommodating cavity is formed between the back cover and the middle frame. In an embodiment, the homothermal structure is located in the accommodating cavity. In an embodiment, the radiating fin is located in the accommodating cavity. In an embodiment, a contact area between the radiating fin and the homothermal structure is changeable.

Another aspect of the present disclosure provides a display apparatus. In an embodiment, the display apparatus includes a display panel and a middle frame assembly. In an embodiment, the middle frame assembly includes a middle frame, a back cover, a homothermal structure, and a radiating fin. In an embodiment, the accommodating cavity is formed between the back cover and the middle frame. In an embodiment, the homothermal structure is located in the accommodating cavity. In an embodiment, the radiating fin is located in the accommodating cavity. A contact area between the radiating fin and the homothermal structure is changeable. In an embodiment, the display panel has a first frequency and a second frequency, the second frequency is greater than the first frequency, and a contact area between the radiating fin and the homothermal structure at the second frequency is smaller than a contact area between the radiating fin and the homothermal structure at the first frequency.

### BRIEF DESCRIPTION OF DRAWINGS

In order to more clearly illustrate technical solutions of embodiments of the present disclosure, the accompanying drawings used in the embodiments are briefly described below. The drawings described below are merely a part of the embodiments of the present disclosure. Based on these drawings, those skilled in the art can obtain other drawings.

FIG. 1 is a structural schematic diagram of a middle frame assembly according to an embodiment of the present disclosure;

FIG. 2 is a schematic diagram of relative movement between a radiating sub-fin and a homothermal structure in FIG. 1 according to an embodiment of the present disclosure;

FIG. 3 is a partial structural schematic diagram of a middle frame assembly according to an embodiment of the present disclosure;

FIG. 4 is a top view of a radiating sub-fin, a controller, and an elastic sheet according to an embodiment of the present disclosure;

FIG. 5 is a partial structural schematic diagram of a middle frame assembly according to another embodiment of the present disclosure;

FIG. 6 is another top view of a radiating sub-fin, a controller, and an elastic sheet according to an embodiment of the present disclosure;

FIG. 7 is a schematic diagram of relative movement between a radiating sub-fin and a homothermal structure in FIG. 5 according to an embodiment of the present disclosure;

FIG. 8 is a partial structural schematic diagram of a middle frame assembly according to another embodiment of the present disclosure;

FIG. 9 is a structural schematic diagram of a middle frame assembly according to another embodiment of the present disclosure;

FIG. 10 is a structural schematic diagram of a middle frame assembly according to an embodiment of the present disclosure;

FIG. 11 is a top view of a radiating sub-fin according to an embodiment of the present disclosure;

FIG. 12 is a structural schematic diagram of a middle frame assembly according to another embodiment of the present disclosure;

FIG. 13 is a schematic diagram of relative movement between a radiating sub-fin and a homothermal structure in FIG. 12 according to an embodiment of the present disclosure;

FIG. 14 is a structural schematic diagram of a middle frame assembly according to another embodiment of the present disclosure;

FIG. 15 is a schematic diagram of relative movement between a radiating sub-fin and a homothermal structure in FIG. 14 according to an embodiment of the present disclosure;

FIG. 16 is a structural schematic diagram of a middle frame assembly according to another embodiment of the present disclosure;

FIG. 17 is a cross-sectional view of the middle frame assembly along a direction A1-A2 shown in FIG. 16 according to an embodiment of the present disclosure;

FIG. 18 is a structural schematic diagram of a middle frame assembly according to another embodiment of the present disclosure;

FIG. 19 is a structural schematic diagram of a display apparatus according to an embodiment of the present disclosure;

FIG. 20 is a structural schematic diagram of a display apparatus holded by a user according to an embodiment of the present disclosure; and

FIG. 21 is a structural schematic diagram of a display apparatus holded by a user according to another embodiment of the present disclosure.

### DESCRIPTION OF EMBODIMENTS

In order to better understand technical solutions of the present disclosure, the embodiments of the present disclosure are described in detail with reference to the drawings.

It should be clear that the described embodiments are merely part of the embodiments of the present disclosure rather than all embodiments. All other embodiments obtained by those skilled in the art shall fall into the protection scope of the present disclosure.

The terms used in the embodiments of the present disclosure are merely for the purpose of describing specific embodiment, rather than limiting the present disclosure. The terms “a”, “an”, “the” and “said” in a singular form in the embodiments of the present disclosure and the attached claims are also intended to include plural forms thereof, unless noted otherwise.

It should be understood that the term “and/or” used in the context of the present disclosure is to describe a correlation relation of related objects, indicating that there may be three relations, e.g., A and/or B may indicate only A, both A and B, and only B. In addition, the symbol “/” in the context generally indicates that the relation between the objects in front and at the back of “/” is an “or” relationship.

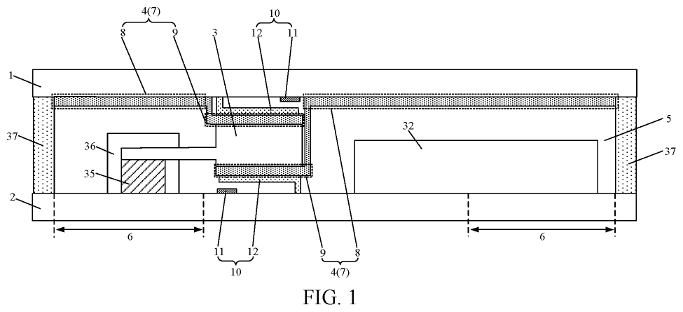

An embodiment of the present disclosure provides a middle frame assembly. FIG. 1 is a structural schematic diagram of the middle frame assembly according to an embodiment of the present disclosure. As shown in FIG. 1, the middle frame assembly includes a back cover 1, a middle frame 2, a homothermal structure 3, and a radiating fin 4. An accommodating cavity 5 is formed between the back cover 1 and the middle frame 2. The homothermal structure 3 and the radiating fin 4 are located in the accommodating cavity 5. The homothermal structure 3 may be a vapor chamber (VC) homothermal pipe configured to improve the heat dissipation efficiency. The radiating fin 4 may be made of heat dissipation materials such as graphene. A contact area between the radiating fin 4 and the homothermal structure 3 is changeable.

The middle frame assembly is used in a display apparatus. The heat generated during the operation of the display apparatus is transferred to the radiating fin 4 through the homothermal structure 3, and finally dissipated from the back cover 1 through the radiating fin 4. The amount of heat dissipated by the radiating fin 4 affects the temperature of the back cover 1. When the user's hands hold the display apparatus, it also affects the temperature felt by the user's hand.

In some embodiments of the present disclosure, the contact area between the radiating fin 4 and the homothermal structure 3 in the middle frame assembly is changeable. That is, in some embodiments of the present disclosure, the contact area between the radiating fin 4 and the homothermal structure 3 can be adjusted to change the heat transferred by the homothermal structure 3 to the radiating fin 4, thereby changing the heat dissipated by the radiating fin 4 through the back cover 1.

Based on this design, when in use and the display apparatus has low power consumption and generates less heat, the contact area between the homothermal structure 3 and the radiating fin 4 can be controlled to be larger. This allows for a greater heat dissipation capacity for the entire radiating fin 4. Since the heat generated by the display apparatus is less, the temperature at different positions on the back cover 1 remains relatively low. As a result, no matter where the user's hands hold the display apparatus, the touch area will not become too hot. Moreover, this design also facilitates uniform heat dissipation throughout the radiating fin 4. In another usage scenario, when the display apparatus has high power consumption and generates more heat, the contact area between the radiating fin 4 and the homothermal structure 3 can be adjusted to change the heat dissipation of the radiating fin 3. For example, the heat dissipation amount of the radiating fin 3 at a local position on the back cover 1 can be reduced to prevent excessive high temperature at this area on the back cover 1. Based on this concept, the back cover temperature of the hand-holding position can be reduced accordingly when the user's hands hold the display apparatus, withnot affecting the user's hand-holding experience due to its excessive high temperature.

In summary, in the present disclosure, the heat dissipation manner of the middle frame assembly is more flexible, so that the temperature on the back cover 1 can be adjusted easily, thus improving the user's experience upon holding the display apparatus.

In some embodiments of the present disclosure, referring to FIG. 1 again, the accommodating cavity 5 includes at least two partitions 6. The radiating fin 4 includes at least two radiating sub-fins 7, each radiating sub-fin 7 corresponds to one partition 6, at least a part of the radiating sub-fin 7 is located in the corresponding partition 6, and a contact area between the radiating sub-fin 7 and the homothermal structure 3 is changeable.

The radiating fin 4 in the above structure includes at least two separate radiating sub-fins 7, and each radiating sub-fin 7 corresponds to one partition 6. This allows for independent control of the temperature of the back cover at different partitions 6 by controlling the contact areas between each radiating sub-fin 7 and the homothermal structure 3.

In some embodiments of the present disclosure, in a usage scenario, for a particular radiating sub-fin 7, a contact area between the radiating sub-fin 7 and the homothermal structure 3 may be controlled to be large, so that the homothermal structure 3 transfers more heat to the radiating sub-fin 7. In this case, the radiating sub-fin 7 dissipates a large amount of heat through the back cover 1, resulting in higher temperature of the back cover at the partition 6 corresponding to the radiating sub-fin 7. In another usage scenario, the contact area between the radiating sub-fin 7 and the homothermal structure 3 may be controlled to be small, so that the homothermal structure 3 transfers less heat to the radiating sub-fin 7. Consequently, the radiating sub-fin 7 dissipates less heat through the back cover 1, resulting in lower temperature of the back cover at the partition 6 corresponding to the radiating sub-fin 7.

Based on this heat dissipation manner, the contact area between the homothermal structure 3 and the radiating sub-fin 7 corresponding to different partitions 6 can be adjusted according to the user's hand-holding position, thereby reducing the temperature of the back cover at the user's hand-holding position.

In the above design, although the heat dissipation amount of a particular radiating sub-fin 7 is reduced, the homothermal structure 3 transfers most heat to other radiating sub-fins 7, allowing most of the heat to be dissipated through other radiating sub-fins 7. For example, when the user holds the bottom of the display apparatus, although the heat dissipation amount of the radiating sub-fin 7 corresponding to the bottom of the display apparatus is reduced, the homothermal structure 3 transfers most heat to the radiating sub-fin 7 corresponding to the top of the display apparatus, thereby allowing most heat to be dissipated through this radiating sub-fin 7. This ensures that the display apparatus still has optimal heat dissipation performance.

Based on the above structure, in some embodiments of the present disclosure, referring to FIG. 1 again, the radiating sub-fin 7 includes a first primary heat dissipation portion 8 and a first adjusting portion 9. The area of the first primary heat dissipation portion 8 may be larger than that of the first adjusting portion 9. The first primary heat dissipation portion 8 is located at a side of the back cover 1. In some embodiments of the present disclosure, the first primary heat dissipation portion 8 may be attached to a surface of the back cover 1 facing the middle frame 2. The first adjusting portion 9 is located at a side of the homothermal structure 3, and contact areas between the first adjusting portion 9 and the homothermal structure 3 in different states are different.

In such a structure, only a part of the first adjusting portion 9 of the radiating sub-fin 7 needs to be controlled to move with respect to the homothermal structure 3, thereby changing the contact area between an entire radiating sub-fin 7 and the homothermal structure 3. On one hand, the movement state of the first adjusting portion 9 is easier to control. On the other hand, the position of the first primary heat dissipation portion 8 with a larger area in the radiating sub-fin 7 can be fixed, so that stable heat dissipation performance of the radiating sub-fin 7 is achieved by using the first primary heat dissipation portion 8.

In some embodiments of the present disclosure, referring to FIG. 1 again, the middle frame assembly further includes at least two first driving components 10, and one first driving component 10 corresponds to one first adjusting portion 9. The first driving component 10 includes a controller 11 and an elastic sheet 12. The elastic sheet 12 is located at a side of the corresponding first adjusting portion 9 away from the homothermal structure 3. A surface of the elastic sheet 12 adjacent to the first adjusting portion 9 is connected to the first adjusting portion 9. For example, the surface of the elastic sheet 12 adjacent to the first adjusting portion 9 is bonded and fixed to the first adjusting portion 9. The controller 11 is located at a side of the elastic sheet 12 away from the homothermal structure 3, and a gap is formed between the controller 11 and the elastic sheet 12. The controller 11 is configured to suck the elastic sheet 12 to move away from the homothermal structure 3 during operation.

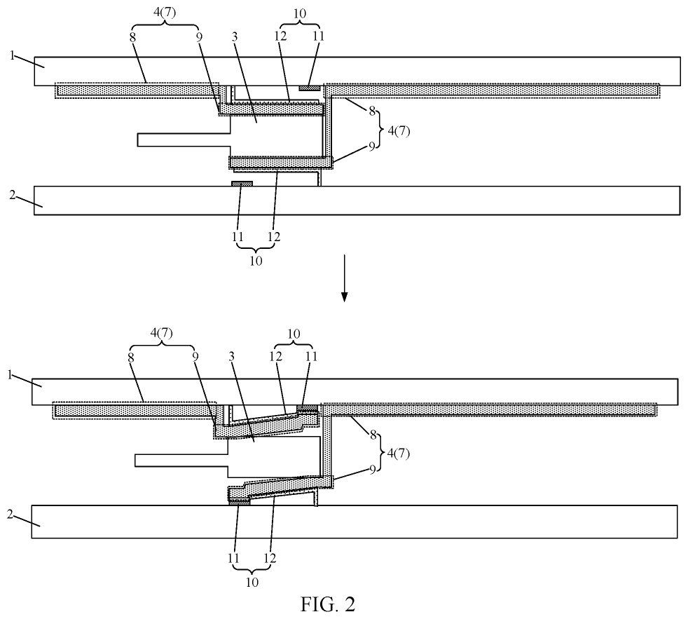

Based on this structure, as shown in FIG. 2, FIG. 2 is a schematic diagram of the relative movement between the radiating sub-fin 7 and the homothermal structure 3 in FIG. 1. When the controller 11 is not working, it exerts no suction force on the elastic sheet 12, and the elastic sheet 12 is pressed against the first adjusting portion 9 to be in close contact with the homothermal structure 3, so that the contact area between the first adjusting portion 9 and the homothermal structure 3 is maximized. When the controller 11 works, the controller 11 sucks the elastic sheet 12 to move away from the homothermal structure 3. Since the elastic sheet 12 is bonded and fixed to the first adjusting portion 9, the elastic sheet 12 further drives at least a part of the first adjusting portion 9 to move away from the homothermal structure 3, so that at least the part of the first adjusting portion 9 loses contact with the homothermal structure 3. This reduces the contact area between the first adjusting portion 9 and the homothermal structure 3, and further reduces the contact area between the whole radiating sub-fin 7 and the homothermal structure 3.

That is, the controller 11 work to control the state of the first adjusting portion 9, thus enabling different contact areas between the first adjusting portion 9 and the homothermal structure 3.

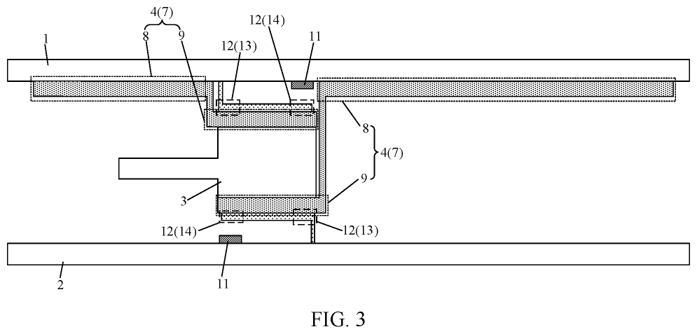

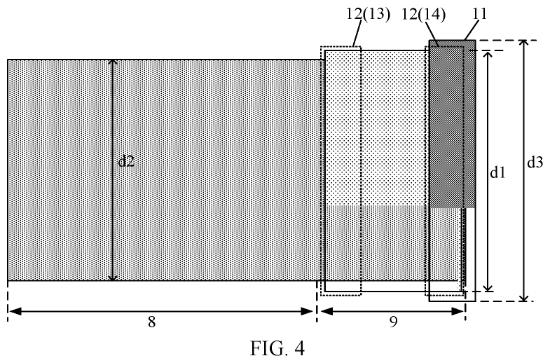

Further, as shown in FIG. 3 and FIG. 4, FIG. 3 is a partial structural schematic diagram of a middle frame assembly according to an embodiment of the present disclosure, and FIG. 4 is a top view of a radiating sub-fin 7, a controller 11, and an elastic sheet 12 according to an embodiment of the present disclosure. The elastic sheet 12 includes a first end 13 and a second end 14 that are opposite to each other. In a direction perpendicular to a plane of the back cover 1, the first end 13 is adjacent to the first primary heat dissipation portion 8, and the controller 11 overlaps with the second end 14.

In the above structure, the controller 11 is adjacent to the second end 14 of the elastic sheet 12. With reference to FIG. 2, when the controller 11 works, it generates a large suction force on the second end 14 of the elastic sheet 12, so that the second end 14 of the elastic sheet 12 upwarps in a direction away from the homothermal structure 3, causing the end of the first adjusting portion 9 to upwarp. When the controller 11 does not work, the suction force generated by the controller 11 on the second end 14 of the elastic sheet 12 disappears, and the second end 14 of the elastic sheet 12 falls, so that the first adjusting portion 9 returns to close contact with the homothermal structure 3.

The above manner reduces the contact area between the first adjusting portion 9 and the homothermal structure 3 by controlling the end of the first adjusting portion 9 to be upwarped. When the end of the first adjusting portion 9 in the radiating sub-fin 7 is upwarped, the contact area between the radiating sub-fin 7 and the homothermal structure 3 is greatly reduced. Thus, the contact area between the radiating sub-fin 7 and the homothermal structure 3 can be greatly decreased, resulting in a significant reduction in the temperature of the back cover at the partition 6 corresponding to the sub-radiating fin 7.

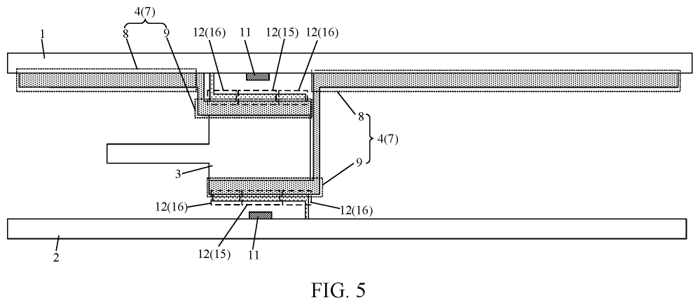

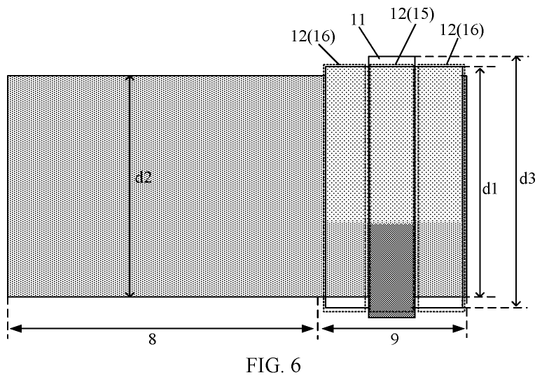

Alternatively, as shown in FIG. 5 and FIG. 6, FIG. 5 is a partial structural schematic diagram of a middle frame assembly according to another embodiment of the present disclosure, and FIG. 6 is another top view of a radiating sub-fin 7, a controller 11, and an elastic sheet 12 according to an embodiment of the present disclosure. The elastic sheet 12 includes a middle portion 15 and edge portions 16. In one arrangement mode, the edge portions 16 may be located at both sides of the middle portion 15, and an arrangement direction of the edge portions 16 and the middle portion 15 is the same as that of the first primary heat dissipation portion 8 and the first adjusting portion 9. The controller 11 overlaps with the middle portion 15 in a direction perpendicular to the plane of the back cover 1.

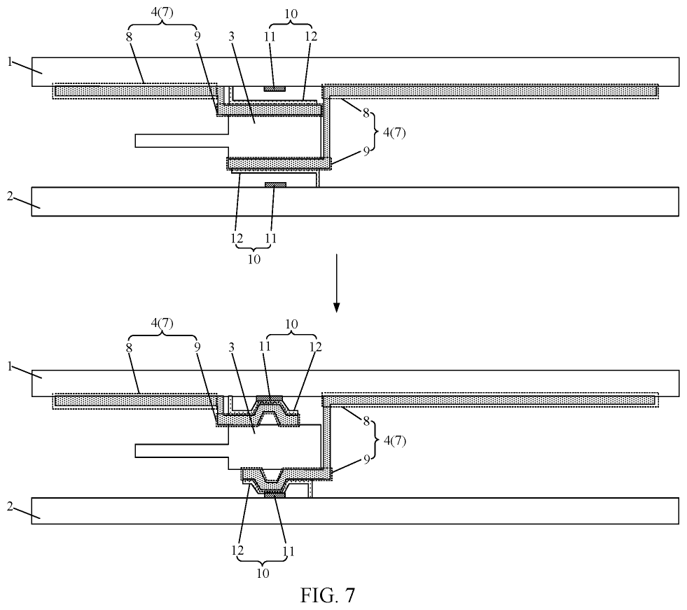

In the above structure, FIG. 7 is a schematic diagram of relative movement between the radiating sub-fin 7 and the homothermal structure 3 in FIG. 5. As shown in FIG. 7, the controller 11 is located at a side of the middle portion 15 of the elastic sheet 12. When the controller 11 works, it generates a suction force on the middle portion 15 of the elastic sheet 12, causing it to arch away from the homothermal structure 3. This causes the middle portion of the first adjusting portion 9 to arch away from the homothermal structure 3. In this case, the edge positions on both sides of the first adjusting portion 9 still maintain contact with the homothermal structure 3, ensuring that the contact area between the first adjusting portion 9 and the homothermal structure 3 from is not reduced too much. While effectively reducing the temperature of the partition 6, a certain contact area is maintained between the radiating sub-fin 7 and the homothermal structure 3. This allows for sufficient heat dissipation from the radiating sub-fin 7, thereby optimizing the overall heat dissipation performance.

In the above two structures, referring to FIG. 4 and FIG. 6 again, a width d1 of the elastic sheet 12 is greater than or equal to a width d2 of the first adjusting portion 9, and a width d3 of the controller 11 is greater than or equal to the width d1 of the elastic sheet 12. A width direction of the elastic sheet 12, a width direction of the first adjusting portion 9, and a width direction of the controller 11 are all parallel to the plane of the back cover 1, and intersect with an arrangement direction of the first primary heat dissipation portion 8 and the first adjusting portion 9.

Such arrangement ensures a sufficient overlapping area between the controller 11 and the elastic sheet 12, enabling the controller 11 to generate enough suction force on the elastic sheet 12. Additionally, it guarantees that there is enough overlapping area between the elastic sheet 12 and the first adjusting portion 9, allowing the elastic sheet 12, when being sucked up, to lift the first adjusting portion 9 with the help of the sufficient overlapping area. This effectively controls the contact area between the first adjusting portion 9 and the homothermal structure 3.

In addition, in some embodiments of the present disclosure, areas of the elastic sheets 12 corresponding to different radiating sub-fins 7 may alternatively be different. For example, if the display apparatus is a mobile phone, no matter whether the mobile phone performs horizontal or vertical display, the user is more likely to hold the bottom of the mobile phone. In this case, the area of the elastic sheet 12 corresponding to the radiating sub-fin 7 located at the bottom of the mobile phone may be larger, to increase the adjusting degree of the elastic sheet 12 on the contact area with the first adjusting portion 9 of the radiating sub-fin 7. When the elastic sheet 12 drives the first adjusting portion 9 in the radiating sub-fin 7 to move, the contact area between the radiating sub-fin 7 and the homothermal structure 3 can be greatly reduced, thereby effectively lowering the temperature of the back cover at the bottom of the mobile phone.

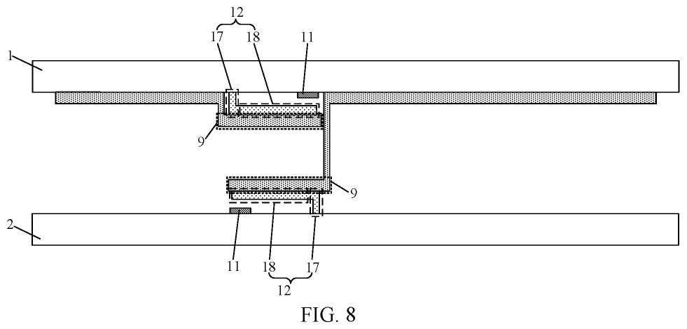

FIG. 8 is a partial structural schematic diagram of a middle frame assembly according to another embodiment of the present disclosure. An elastic sheet 12 includes a first portion 17 and a second portion 18, the first portion 17 is connected to a back cover 1 or a middle frame 2, and the second portion 18 is adjacent to the surface of a first adjusting portion 9 and connected to the first adjusting portion 9. For example, the first portion 17 is bonded and fixed to the back cover 1 or the middle frame 2, and the second portion 18 is adjacent to the surface of the first adjusting portion 9 and bonded and fixed to the first adjusting portion 9. In addition, a gap is formed between the second portion 18 and the controller 11.

In this case, the elastic sheet 12 may have a L-shape, the first portion 17 is a short part of the elastic sheet 12, and the second portion 18 is a long part of the elastic sheet 12. The first portion 17 of the elastic sheet 12 is fixed to the back cover 1 or the middle frame 2 to achieve fixation with the back cover 1 or the middle frame 2. When the controller 11 controls the second portion 18 of the elastic sheet 12 to upwarp, the first portion 17 of the elastic sheet 12 presses the first adjusting portion 9 in contact with the first portion 17, to contact with the homothermal structure 3, thus ensuring that a part of the first adjusting portion 9 maintains contact with the homothermal structure 3. Such arrangement effectively reduces the temperature of the partition 6 while also maintaining a contact area between the radiating sub-fin 7 and the homothermal structure 3, thereby optimizing the overall heat dissipation performance.

In some embodiments of the present disclosure, the controller 11 includes an electromagnetic device, and the elastic sheet 12 may be a metal elastic sheet 12. When the controller 11 works, it utilizes a magnetic force to move the elastic sheet 12.

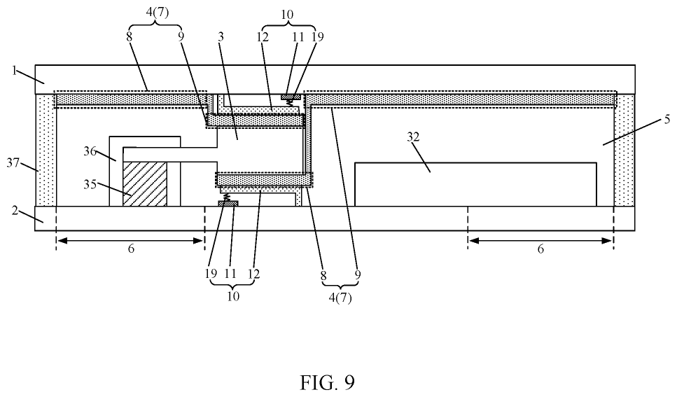

In some embodiments of the present disclosure, as shown in FIG. 9, FIG. 9 is a structural schematic diagram of a middle frame assembly according to another embodiment of the present disclosure. A first driving component 10 further includes a spring 19 located between a controller 11 and an elastic sheet 12. One end of the spring 19 is connected to the controller 11, and the other end of the spring 19 is connected to the elastic sheet 12.

When the controller 11 works to suck the elastic sheet 12, the spring 19 is compressed. When the controller 11 does not work, the suction force on the elastic sheet 12 disappears, and the spring 19 extends, exerting a force on the elastic sheet 12 towards a homothermal structure 3, thus pushing a first adjusting portion 9 to come into close contact with the homothermal structure 3.

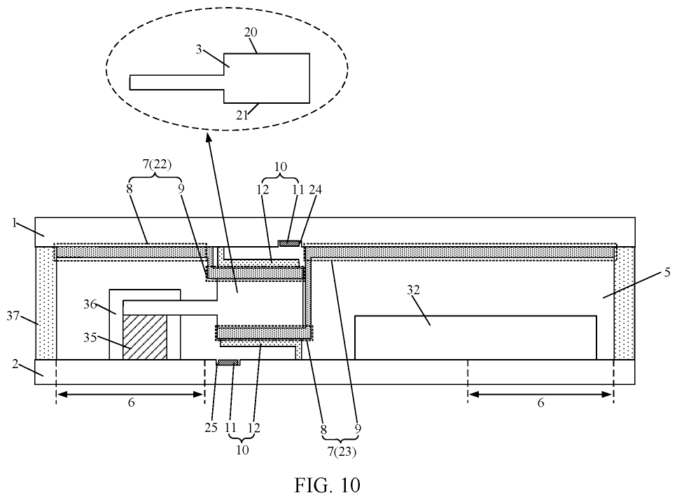

In some embodiments of the present disclosure, as shown in FIG. 10, FIG. 10 is a structural schematic diagram of a middle frame assembly according to another embodiment of the present disclosure. A homothermal structure 3 includes a first surface 20 and a second surface 21 that are opposite to each other. The first surface 20 faces a back cover 1, and the second surface 21 faces a middle frame 2. At least two radiating sub-fins 7 include a first radiating sub-fin 22 and a second radiating sub-fin 23. A first adjusting portion 9 of the first radiating sub-fin 22 is located at the first surface 20, and a first adjusting portion 9 of the second radiating sub-fin 23 is located on the second surface 21.

In this case, the first adjusting portions 9 of the first radiating sub-fin 22 and the second radiating sub-fin 23 are located at the opposite sides of the homothermal structure 3, and the homothermal structure 3 can have larger contact areas with both the first adjusting portions 9 when in close contact with the first adjusting portions 9. Therefore, when the contact area between the first adjusting portion 9 and the homothermal structure 3 is reduced, the temperature of the back cover at the partition 6 can be significantly reduced.

Further, referring to FIG. 10, the back cover 1 includes a first groove 24, and the controller 11 corresponding to the first radiating sub-fin 22 is located in the first groove 24, and/or the middle frame 2 includes a second groove 25, and the controller 11 corresponding to the second radiating sub-fin 23 is located in the second groove 25.

In this way, when the distance between the back cover 1 and the middle frame 2 is fixed, sufficient gaps can be ensured between the elastic sheet 12 corresponding to the first radiating sub-fin 22 and the controller 11, as well as between the elastic sheet 12 corresponding to the second radiating sub-fin 23 and the controller 11. When the controller 11 sucks the elastic sheet 12, the upwarping or arching degree of the elastic sheet 12 can be increased, thereby effectively regulating the contact area between the radiating sub-fin 7 and the homothermal structure 3.

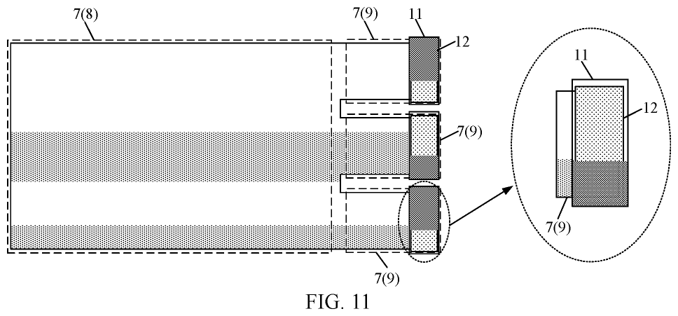

In a possible implementation, as shown in FIG. 11, FIG. 11 is a top view of a radiating sub-fin 7 according to an embodiment of the present disclosure. The radiating sub-fin 7 includes at least two first adjusting portions 9.

In this case, the temperature of the partition 6 can be adjusted to different degrees by controlling different first adjusting portions 9 in the same radiating sub-fin 7 to be in different states. For example, when all the first adjusting portions 9 in the radiating sub-fin 7 are in close contact with the homothermal structure 3, the contact area between the radiating sub-fin 7 and the homothermal structure 3 is maximized. As more first adjusting portions 9 in the radiating sub-fin 7 are controlled to upwarp or arch, the contact area between the radiating sub-fin 7 and the homothermal structure 3 is further decreased. Consequently, the contact area between the radiating sub-fin 7 and the homothermal structure 3 becomes smaller.

This can control the temperature of the partitions 6 more accurately and flexibly. For example, when the display apparatus performs ultra high frequency (UHF) display, the display apparatus generates a lot of heat. In order to avoid overheating in the hand-holding position, all the first adjusting portions 9 in the radiating sub-fin 7 corresponding to the bottom of the display apparatus can be controlled to upwarp or arch. When the display apparatus performs high-frequency display, the heat generated by the display apparatus is slightly lower. In this case, some of the first adjusting portions 9 in the radiating sub-fin 7 corresponding to the bottom of the mobile phone can be controlled to upwarp or arch.

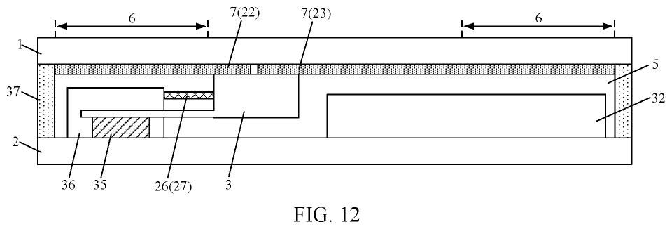

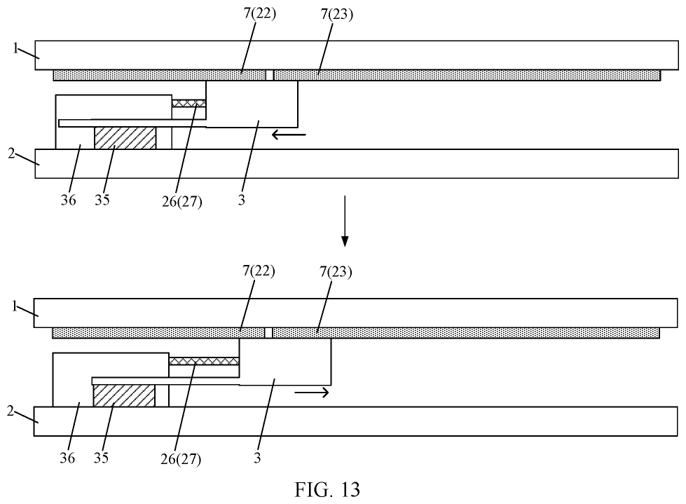

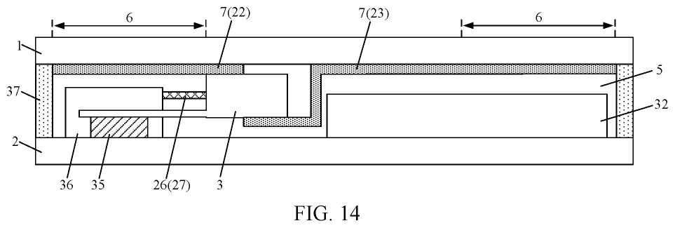

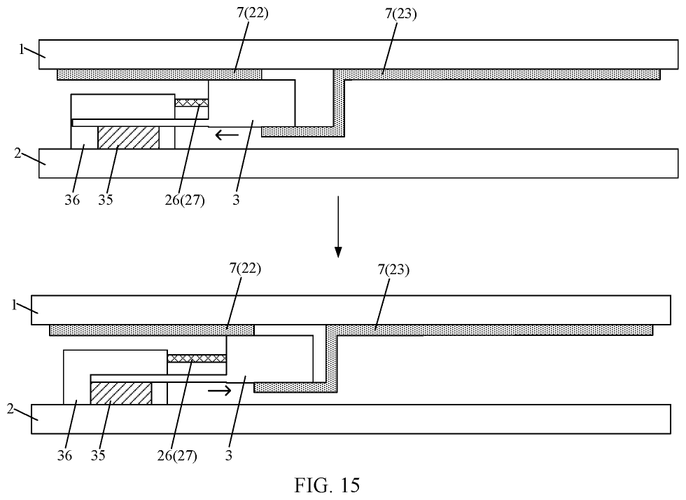

FIG. 12 is a structural schematic diagram of a middle frame assembly according to another embodiment of the present disclosure, and FIG. 13 is a schematic diagram of relative movement between a radiating sub-fin 7 and a homothermal structure 3 in FIG. 12. FIG. 14 is a structural schematic diagram of a middle frame assembly according to another embodiment of the present disclosure, and FIG. 15 is a schematic diagram of relative movement between a radiating sub-fin 7 and a homothermal structure 3 in FIG. 14. At least two radiating sub-fins 7 include a first radiating sub-fin 22 and a second radiating sub-fin 23, and positions of the first radiating sub-fin 22 and the second radiating sub-fin 23 are fixed.

The middle frame assembly further includes a second driving component 26 connected to the homothermal structure 3 and configured to drive the homothermal structure 3 to move relative to the first radiating sub-fin 22 and the second radiating sub-fin 23, causing the contact area between the first radiating sub-fin 22 and the homothermal structure 3 and the contact area between the second radiating sub-fin 23 and the homothermal structure 3 to vary. When the homothermal structure 3 moves relative to the first radiating sub-fin 22 and the second radiating sub-fin 23, one of the contact area between the first radiating sub-fin 22 and the homothermal structure 3 and the contact area between the second radiating sub-fin 23 and the homothermal structure 3 increases, and the other one decreases.

In such arrangement mode, the positions of the first radiating sub-fin 22 and the second radiating sub-fin 23 are fixed, and the contact area between the homothermal structure 3 and the radiating sub-fin 7 is changed by controlling the movement of the homothermal structure 3. For example, controlling the homothermal structure 3 to move towards the top of the display apparatus can increase the contact area between the homothermal structure 3 and the radiating sub-fin 7 corresponding to the top of the display apparatus, while decreasing the contact area between the homothermal structure 3 and the radiating sub-fin 7 corresponding to the bottom of the display apparatus. In this case, the heat dissipation through the radiating sub-fin 7 corresponding to the bottom of the display apparatus is reduced, the temperature of the back cover at the bottom of the display apparatus is lowered, and more heat is dissipated through the back cover 1 at the top of the display apparatus.

Further, with reference to FIG. 12 and FIG. 13, the first radiating sub-fin 22 and the second radiating sub-fin 23 are located at a same side of the back cover 1, and the second driving component 26 is configured to drive the homothermal structure 3 to move in an arrangement direction of the first radiating sub-fin 22 and the second radiating sub-fin 23. In this case, both the first radiating sub-fin 22 and the second radiating sub-fin 23 are attached to the back cover 1, thereby achieving a simple structure and low design difficulty.

Furthermore, referring to FIG. 12 to FIG. 15 again, the second driving component 26 includes a telescopic rod 27, and the telescopic rod 27 elongates or contracts, pulling the homothermal structure 3 to move relative to the first radiating sub-fin 22 and the second radiating sub-fin 23. In some embodiments of the present disclosure, one end of the telescopic rod 27 may be connected to a heat shield 36, and the other end may be connected to the homothermal structure 3, so that one end of the telescopic rod 27 remains to be fixed while the telescopic rod 27 elongates or contracts to drive the movement of the homothermal structure 3.

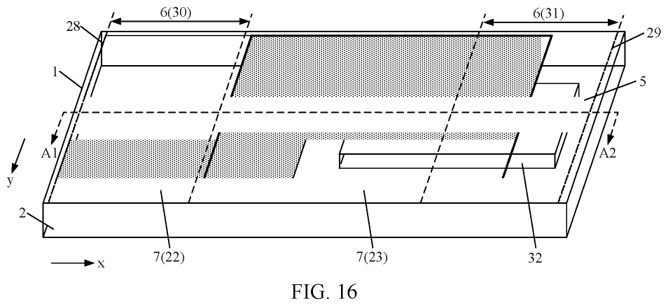

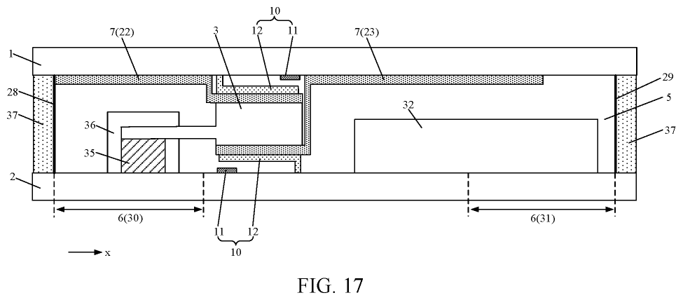

FIG. 16 is a structural schematic diagram of a middle frame assembly according to another embodiment of the present disclosure, and FIG. 17 is a sectional view of the middle frame assembly along a direction A1-A2 shown in FIG. 16. A length of the middle frame assembly in a first direction x is greater than a length of the middle frame assembly in a second direction y, and the first direction x intersects the second direction y.

An accommodating cavity 5 includes a first edge 28 and a second edge 29 that are opposite in the first direction x, and at least two partitions 6 include a first partition 30 and a second partition 31 arranged along the first direction x, one edge of the first partition 30 is the first edge 28, and one edge of the second partition 31 is the second edge 29.

When the length of the middle frame assembly in the first direction x is greater than that in the second direction y, the middle frame assembly has a long strip structure, and the display apparatus to which it applies is also a long strip structure. Most of these display apparatuses are electronic products such as mobile phones. In this structure, because the first partition 30 and the second partition 31 in the accommodating cavity 5 are located at two sides of the accommodating cavity 5, the first partition 30 and the second partition 31 may correspond to the top and the bottom of the display apparatus. In this way, the areas of the first partition 30 and the second partition 31 correspond to the common hand-holding positions when users hold the display apparatus. Therefore, by adjusting the temperature of the back cover at the first partition 30 and the second partition 31, the temperature at the user's hand-holding position can be adjusted.

In some embodiments of the present disclosure, when the display apparatus operates at a high frequency, it generates more heat. In this case, the contact area between the radiating sub-fin 7 corresponding to the first partition 30 and the homothermal structure 3 can be reduced to be smaller than the contact area between the radiating sub-fin 7 corresponding to the first partition 30 and the homothermal structure 3 during low-frequency operation, and/or the contact area between the radiating sub-fin 7 corresponding to the second partition 31 and the homothermal structure 3 can be reduced to be smaller than the contact area between the radiating sub-fin 7 corresponding to the second partition 31 and the homothermal structure 3 during low-frequency operation. Therefore, the temperature of the back cover at the first partition 30 and/or the second partition 31 is reduced when the display apparatus operates at a high frequency, preventing overheating of the user's hand when touching the area. The specific process is described in detail below in the following embodiments of the display apparatus.

Further, referring to FIG. 16 and FIG. 17 again, the middle frame assembly further includes a battery 32, and the battery 32 is located in the accommodating cavity 5 and at least partially located in the second partition 31. The at least two radiating sub-fins 7 include a first radiating sub-fin 22 corresponding to the first partition 30 and a second radiating sub-fin 23 corresponding to the second partition 31, and a distance between the second radiating sub-fin 23 and the second edge 29 is longer than a distance between the first radiating sub-fin 22 and the first edge 28. In one arrangement mode, the distance between the first radiating sub-fin 22 and the first edge 28 may be 0, that is, one edge of the first radiating sub-fin 22 coincides with the first edge 28.

The battery 32 is usually located at the bottom of the display apparatus, and the second partition 31 may be regarded as an area corresponding to the bottom of the display apparatus. Due to the long strip design of the middle frame assembly (display apparatus), users tend to hold the bottom of the display apparatus more frequently, regardless of whether they are viewing the screen horizontally or vertically. In some embodiments of the present disclosure, the second radiating sub-fin 23 is designed not to extend all the way to the edge of the second partition 31, and therefore part of the second partition 31 is not provided with the second radiating sub-fin 23. Therefore, the area of the second radiating sub-fin 23 in the second partition 31 is reduced, which leads to decreased heat dissipation in the second partition 23. As a result, the temperature of the back cover at the second partition 31 is lowered, improving the user's experience upon holding the display apparatus.

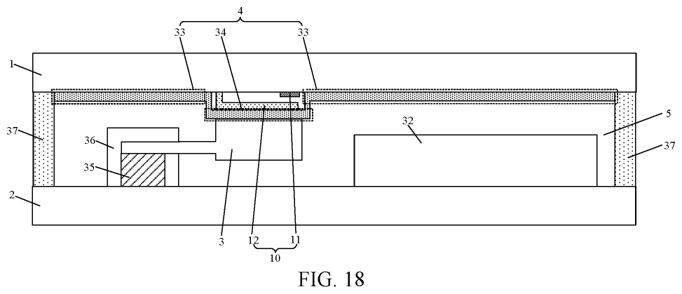

In some embodiments of the present disclosure, as shown in FIG. 18, FIG. 18 is a structural schematic diagram of a middle frame assembly according to another embodiment of the present disclosure. In a direction perpendicular to the middle frame assembly, a radiating fin 4 covers a part of a back cover 1 in an accommodating cavity 5.

The radiating fin 4 includes a second primary heat dissipation portion 33 and a second adjusting portion 34 that are communicated. The second primary heat dissipation portion 33 is located at a side of the back cover 1, and a gap is formed between the second adjusting portion 34 and the back cover 1. A contact area between the second adjusting portion 34 and the homothermal structure 3 varies in different states. In some embodiments of the present disclosure, the contact area between the second adjusting portion 34 and the homothermal structure 3 can be adjusted by the controller 11 and the elastic sheet 12, and the adjustment mode is similar to that in the previous embodiments. Details are not repeated herein.

In such arrangement mode, the radiating fin 4 is a whole surface structure. By changing the contact area between the second adjusting portion 34 and the homothermal structure 3, the temperature at an entire position on the back cover 1 can be changed. This, in turn, changes the temperature at the hand-holding position.

In some embodiments of the present disclosure, referring to FIG. 1 again, the middle frame assembly further includes a heat source 35 and a heat shield 36. The heat source 35 is located in the accommodating cavity 5 and is a critical heating element, which may include a driving chip or the like. The heat source 35 is in contact with the homothermal structure 3 to transfer heat to the radiating fin 4 through the homothermal structure 3. The heat shield 36 is located in the accommodating cavity 5 and covers the heat source 35, to prevent the heat emitted by the heat source 35 from accumulating at a position on the back cover 1 adjacent to the heat source 35. Instead, the heat is transferred to the radiating sub-fin 7 through the homothermal structure 3, and is dissipated at multiple positions, avoiding local overheating.

In addition, referring to FIG. 1 again, the middle frame 2 and the back cover 1 may be bonded together by sealant 37 to form the accommodating cavity 5.

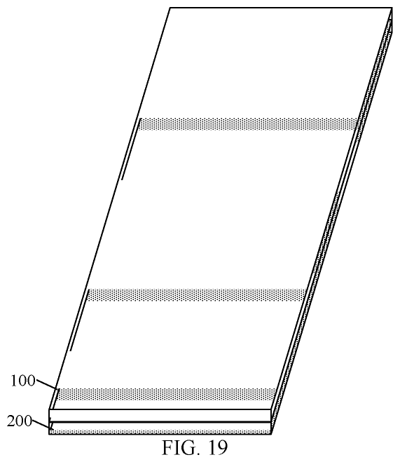

Based on a same inventive concept, an embodiment of the present disclosure further provides a display apparatus. As shown in FIG. 19, FIG. 19 is a structural schematic diagram of a display apparatus according to an embodiment of the present disclosure. The display apparatus includes a display panel 100 and the middle frame assembly 200 mentioned above.

The display panel 100 has a first frequency and a second frequency, and the second frequency is greater than the first frequency. The contact area between the radiating fin 4 and the homothermal structure 3 at the second frequency is smaller than that at the first frequency.

With reference to the previous description of the middle frame assembly 200, in some embodiments of the present disclosure, the contact area between the radiating fin 4 and the homothermal structure 3 in the middle frame assembly 200 is changeable. Therefore, in the display apparatus including the middle frame assembly 200, when the display panel 100 operates at a lower frequency, that is, the first frequency, the power consumption is low, and less heat is generated. In this case, the larger contact area between the homothermal structure 3 and the radiating fin 4 makes the back cover 1 dissipate heat evenly. Since the heat generated by the display apparatus is less, the temperature at different positions on the back cover 1 remains relatively low. As a result, regardless of where the user holds the apparatus, the touch area will not become too hot. When the display panel 100 operates at a higher frequency, that is, the second frequency, the power consumption of the display apparatus is high, and the generated heat is relatively more. In this case, the contact area between the radiating fin 4 and the homothermal structure 3 can be reduced. For example, the heat dissipation amount of the radiating fin 3 at a local position on the back cover 1 can be reduced to prevent excessive high temperature at this area on the back cover 1. Based on this concept, the back cover temperature of the hand-holding position can be reduced accordingly when the user's hands hold the display apparatus, to avoid its excessively high temperature affecting the user's hand-holding experience.

In some embodiments of the present disclosure, referring to FIG. 1, the accommodating cavity 5 includes at least two partitions 6. The radiating fin 4 includes at least two radiating sub-fins 7, each radiating sub-fin 7 corresponds to one partition 6, at least a part of the radiating sub-fin 7 is located in the corresponding partition 6, and the contact area between the radiating sub-fin 7 and the homothermal structure 3 is changeable.

At the first frequency, there is a first contact area between the radiating sub-fin 7 and the homothermal structure 3, and the first contact area may be the maximum contact area between the radiating sub-fin 7 and the homothermal structure 3. At the second frequency, a contact area between at least one of the radiating sub-fins 7 and the homothermal structure 3 is smaller than the first contact area. Therefore, the back cover temperature of at least one of the partitions 6 is reduced when the display apparatus operates at a high frequency, preventing overheating at the touching positions of user's hands.

Further, with reference to FIG. 16 and FIG. 17, the length of the middle frame assembly 200 in a first direction x is greater than that in a second direction y, and the first direction x intersects the second direction y. The accommodating cavity 5 includes a first edge 28 and a second edge 29 that are opposite in the first direction x, and the at least two partitions 6 include a first partition 30 and a second partition 31 arranged along the first direction x, one edge of the first partition 30 is the first edge 28, and one edge of the second partition 31 is the second edge 29.

At the second frequency, the contact area between the radiating sub-fin 7 corresponding to the first partition 30 and the homothermal structure 3 is smaller than the first contact area, and/or the contact area between the radiating sub-fin 7 corresponding to the second partition 31 and the homothermal structure 3 is smaller than the first contact area.

With reference to the foregoing description, the second partition 31 may correspond to the bottom of the display apparatus, and correspondingly, the first partition 30 may correspond to the top of the display apparatus. Detailed descriptions are made by using the following three usage scenarios as examples.

### First Usage Scenario:

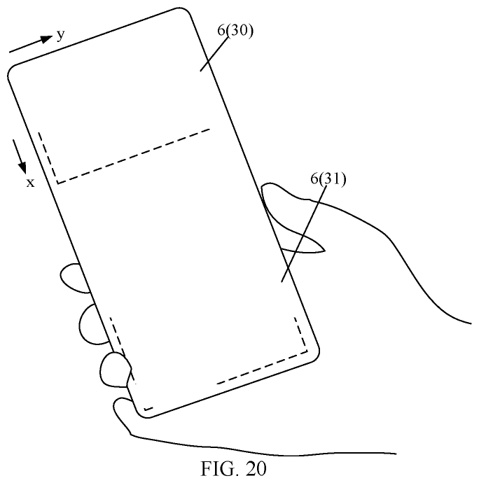

At the second frequency, when the display apparatus performs vertical display and operates at a high frequency, as shown in FIG. 20, FIG. 20 is a structural schematic diagram of a user holding the display apparatus according to an embodiment of the present disclosure. In this usage scenario, the user usually holds the bottom and the middle portions of the display apparatus. In this case, the contact area between the radiating sub-fin 7 corresponding to the second partition 31 and the homothermal structure 3 may be set to be smaller than the first contact area. For example, the controller 11 may be configured to control the movement of the elastic sheet 12. Further, the first adjusting portion 9 in the radiating sub-fin 7 corresponding to the second partition 31 is driven to upwarp, to reduce the contact area between the radiating sub-fin 7 and the homothermal structure 3. This reduces the heat dissipation amount of the radiating sub-fin 7 corresponding to the bottom of the display apparatus, further reduces the temperature of the back cover at the bottom of the display apparatus, and prevents excessive heat feeled by the user's hand.

It should be noted that in this usage scenario, the homothermal structure 3 can transfer most heat to the radiating sub-fin 7 corresponding to the first partition 30, so that most heat can be dissipated through the radiating sub-fin 7 corresponding to the first partition 30, thereby ensuring the overall heat dissipation performance.

### Second Usage Scenario:

According to FIG. 16 and FIG. 17, in an arrangement mode of the embodiments of the present disclosure, the radiating sub-fin 7 (the second radiating sub-fin 23) corresponding to the second partition 31 may not extend to the second edge 29 of the accommodating cavity 5.

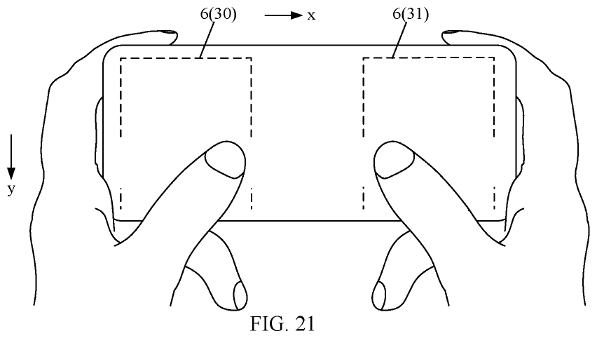

Based on this, at the second frequency, when the display apparatus performs horizontal display at the high frequency, as shown in FIG. 21, FIG. 21 is another schematic diagram of a user holding the display apparatus according to an embodiment of the present disclosure. The user usually holds the bottom and top of the display apparatus. Because there is no radiating sub-fin 7 in part of the second partition 31, the heat is hardly dissipated from this area. Therefore, the temperature of the back cover at the second partition 31 is not too high. In this case, only the contact area between the radiating sub-fin 7 corresponding to the first partition 30 and the homothermal structure 3 may be set to be smaller than the first contact area. This reduces the heat dissipation amount of the radiating sub-fin 7 corresponding to the top of the display apparatus, further reducing the temperature of the back cover at the top of the display apparatus.

### Third Usage Scenario:

At the second frequency, when the display apparatus performs horizontal display, referring to FIG. 21 again, the contact area between the radiating sub-fin 7 corresponding to the first partition 30 and the homothermal structure 3 and the contact area between the radiating sub-fin 7 corresponding to the second partition 31 and the homothermal structure 3 are both set to be smaller than the first contact area, so as to reduce the heat dissipation amount of both the radiating sub-fins 7 corresponding to the first partition 30 and the second partition 31.

In some embodiments of the present disclosure, when the display panel 100 operates at a frequency greater than or equal to 120 Hz, the display apparatus generates more heat. Therefore, in some embodiments of the present disclosure, the second frequency may be set to be greater than or equal to 120 Hz, so that the contact area between at least one of the radiating sub-fins 7 and the homothermal structure 3 can be adjusted in the case of or above 120 Hz, to avoid excessive high temperature of at least a part of the back cover 1.

The above are merely exemplary embodiments of the present disclosure, which, as mentioned above, are not used to limit the present disclosure. Whatever within the principles of the present disclosure, including any modification, equivalent substitution, improvement, etc., shall fall into the protection scope of the present disclosure.

Finally, it should be noted that the technical solutions of the present disclosure are illustrated by the above embodiments, but not intended to limit thereto. Although the present disclosure has been described in detail with reference to the foregoing embodiments, those skilled in the art can understand that the present disclosure is not limited to the specific embodiments described herein, and can make various modifications, readjustments, and substitutions without departing from the scope of the present disclosure.

What is claimed is:

1. A middle frame assembly, comprising:
a middle frame;
a back cover, wherein an accommodating cavity is formed between the back cover and the middle frame;
a homothermal structure located in the accommodating cavity; and
a radiating fin located in the accommodating cavity, wherein a contact area between the radiating fin and the homothermal structure is changeable.

2. The middle frame assembly according to claim 1, wherein the accommodating cavity comprises at least two partitions; and
wherein the radiating fin comprises at least two radiating sub-fins, one of the at least two radiating sub-fins corresponds to one of the at least two partitions, at least a part of one of the at least two radiating sub-fins is located in one corresponding partition of the at least two partitions, and a contact area between one of the at least two radiating sub-fins and the homothermal structure is changeable.

3. The middle frame assembly according to claim 2, wherein one of the at least two radiating sub-fins comprises a first primary heat dissipation portion and a first adjusting portion that are communicated with each other, the first primary heat dissipation portion is located at a side of the back cover, the first adjusting portion is located at a side of the homothermal structure, and a contact area between the first adjusting portion and the homothermal structure varies in different states of the first adjusting portion.

4. The middle frame assembly according to claim 3, further comprising at least two first driving components, and one of the at least two first driving components corresponds to the first adjusting portion; and
wherein one of the at least two first driving components comprises a controller and an elastic sheet, the elastic sheet is located at a side of the first adjusting portion away from the homothermal structure, a surface of the elastic sheet adjacent to the first adjusting portion is connected to the first adjusting portion, the controller is located at a side of the elastic sheet away from the homothermal structure, a gap is formed between the controller and the elastic sheet, and the controller is configured to suck the elastic sheet to move in a direction away from the homothermal structure during operation.

5. The middle frame assembly according to claim 4, wherein the elastic sheet comprises a first end and a second end that are opposite to each other; and
wherein, in a direction perpendicular to a plane of the back cover, the first end is adjacent to the first primary heat dissipation portion, and the controller overlaps the second end.

6. The middle frame assembly according to claim 4, wherein the elastic sheet comprises a middle portion and an edge portion, and the controller overlaps with the middle portion in a direction perpendicular to a plane of the back cover.

7. The middle frame assembly according to claim 5, wherein a width of the elastic sheet is greater than or equal to a width of the first adjusting portion, and a width of the controller is greater than or equal to the width of the elastic sheet; and
wherein a width direction of the elastic sheet, a width direction of the first adjusting portion, and a width direction of the controller are parallel to the plane of the back cover, respectively, and intersect with an arrangement direction of the first primary heat dissipation portion and the first adjusting portion.

8. The middle frame assembly according to claim 4, wherein the elastic sheet comprises a first portion and a second portion, the first portion is connected to the back cover or the middle frame, a surface of the second portion adjacent to the first adjusting portion is connected to the first adjusting portion, and a gap is formed between the second portion and the controller.

9. The middle frame assembly according to claim 4, wherein one of the at least two first driving components further comprises a spring located between the controller and the elastic sheet, one end of the spring is connected to the controller, and the other end of the spring is connected to the elastic sheet.

10. The middle frame assembly according to claim 4, wherein the homothermal structure comprises a first surface and a second surface that are opposite to each other, the first surface faces the back cover, and the second surface faces the middle frame; and
wherein the at least two radiating sub-fins comprise a first radiating sub-fin and a second radiating sub-fin, the first adjusting portion of the first radiating sub-fin is located at a side of the first surface, and the first adjusting portion of the second radiating sub-fin is located at a side of the second surface.

11. The middle frame assembly according to claim 10, wherein the back cover comprises a first groove, the controller corresponding to the first radiating sub-fin is located in the first groove, and/or the middle frame comprises a second groove, and the controller corresponding to the second radiating sub-fin is located in the second groove.

12. The middle frame assembly according to claim 4, wherein one of the at least two radiating sub-fins comprises at least two first adjusting portions.

13. The middle frame assembly according to claim 2, wherein the at least two radiating sub-fins comprise a first radiating sub-fin and a second radiating sub-fin, and positions of the first radiating sub-fin and the second radiating sub-fin are fixed; and
wherein the middle frame assembly further comprises a second driving component connected to the homothermal structure to drive the homothermal structure to move relative to the first radiating sub-fin and the second radiating sub-fin, so that a contact area between the first radiating sub-fin and the homothermal structure and a contact area between the second radiating sub-fin and the homothermal structure are changeable; wherein, when the homothermal structure moves relative to the first radiating sub-fin and the second radiating sub-fin, one of the contact area between the first radiating sub-fin and the homothermal structure and the contact area between the second radiating sub-fin and the homothermal structure increases, and the other of the contact area between the first radiating sub-fin and the homothermal structure and the contact area between the second radiating sub-fin and the homothermal structure decreases.

14. The middle frame assembly according to claim 13, wherein the first radiating sub-fin and the second radiating sub-fin are located at a side of the back cover, and the second driving component is configured to pull the homothermal structure to move along an arrangement direction of the first radiating sub-fin and the second radiating sub-fin.

15. The middle frame assembly according to claim 2, wherein a length of the middle frame assembly in a first direction is greater than a length of the middle frame assembly in a second direction, and the first direction intersects with the second direction; and
wherein the accommodating cavity comprises a first edge and a second edge that are opposite in the first direction, and the at least two partitions comprise a first partition and a second partition arranged along the first direction, one edge of the first partition is the first edge, and one edge of the second partition is the second edge.

16. The middle frame assembly according to claim 15, further comprising a battery, wherein the battery is located in the accommodating cavity and at least partially located in the second partition; and
wherein the at least two radiating sub-fins comprise a first radiating sub-fin corresponding to the first partition and a second radiating sub-fin corresponding to the second partition, and a distance between the second radiating sub-fin and the second edge is longer than a distance between the first radiating sub-fin and the first edge.

17. The middle frame assembly according to claim 1, wherein in a direction perpendicular to a plane of the middle frame assembly, the radiating fin covers a part of the back cover located in the accommodating cavity; and
wherein the radiating fin comprises a second primary heat dissipation portion and a second adjusting portion that are communicated with each other, the second primary heat dissipation portion is located at a side of the back cover, a gap is formed between the second adjusting portion and the back cover, and a contact area between the second adjusting portion and the homothermal structure varies in different states of the second adjusting portion.

18. A display apparatus, comprising a display panel and a middle frame assembly,
wherein the middle frame assembly comprises:
a middle frame;
a back cover, wherein an accommodating cavity is formed between the back cover and the middle frame;
a homothermal structure located in the accommodating cavity; and
a radiating fin located in the accommodating cavity, wherein a contact area between the radiating fin and the homothermal structure is changeable;
wherein the display panel comprises a first frequency and a second frequency, the second frequency is greater than the first frequency, and a contact area between the radiating fin and the homothermal structure at the second frequency is smaller than a contact area between the radiating fin and the homothermal structure at the first frequency.

19. The display apparatus according to claim 18, wherein the accommodating cavity comprises at least two partitions;
wherein the radiating fin comprises at least two radiating sub-fins, one of the at least two radiating sub-fins corresponds to one of the partitions, at least a part of the at least two radiating sub-fins is located in the corresponding partition, and a contact area between one of the at least two radiating sub-fins and the homothermal structure is changeable; and
wherein at the first frequency, there is a first contact area between one of the at least two radiating sub-fins and the homothermal structure, and at the second frequency, a contact area between at least one of the at least two radiating sub-fins and the homothermal structure is smaller than the first contact area.

20. The display apparatus according to claim 19, wherein a length of the middle frame assembly in a first direction is greater than a length of the middle frame assembly in a second direction, and the first direction intersects with the second direction;
wherein the accommodating cavity comprises a first edge and a second edge that are opposite in the first direction, the at least two partitions comprise a first partition and a second partition arranged along the first direction, one edge of the first partition is the first edge, and one edge of the second partition is the second edge; and
wherein at the second frequency, the contact area between one of the at least two radiating sub-fins corresponding to the first partition and the homothermal structure is smaller than the first contact area, and/or the contact area between one of the at least two radiating sub-fins corresponding to the second partition and the homothermal structure is smaller than the first contact area.
